(19) United States
(12) Patent Application Publication
(10) Pub. No.: US 2025/0006823 A1
(43) Pub. Date: Jan. 2, 2025

(54) SEMICONDUCTOR DEVICE INCLUDING A BIPOLAR JUNCTION TRANSISTOR

(71) Applicant: Infineon Technologies AG, Neubiberg (DE)

(72) Inventor: Josef Schweda, Villach (AT)

(21) Appl. No.: 18/741,883

(22) Filed: Jun. 13, 2024

(30) Foreign Application Priority Data
Jun. 27, 2023 (DE) 102023206017.5

(51) Int. Cl. H01L 29/73; H01L 27/06; H01L 29/06; H01L 29/40; H01L 29/66

(52) U.S. Cl. CPC H01L 29/73; H01L 27/0623; H01L 29/0649; H01L 29/402; H01L 29/66234

(57) ABSTRACT

A semiconductor device includes a semiconductor body having opposing first and second surfaces along a vertical direction, and a bipolar junction transistor that includes an emitter region electrically connected to an emitter contact at the first surface, a base region electrically connected to a base contact at the first surface, and a collector region electrically connected to a collector contact. A dielectric isolation structure extends into the semiconductor body from the first surface and includes a first sub-structure arranged, along a first lateral direction, between the emitter contact and the base contact. A field plate structure including a field plate dielectric and a field plate electrode is arranged on the field plate dielectric. A first part of the field plate structure is arranged on the first surface of the semiconductor body. A second part of the field plate structure is arranged on the first sub-structure of the dielectric isolation structure.

### TECHNICAL FIELD

The present disclosure is related to a semiconductor device, in particular to a semiconductor device comprising a bipolar junction transistor, BJT.

### BACKGROUND

Technology development of new generations of semiconductor devices, e.g. bipolar junction transistors, aims at improving electric device characteristics and reducing costs by shrinking device geometries. Although costs may be reduced by shrinking device geometries, a variety of tradeoffs and challenges have to be met when increasing device functionalities per unit area. For example, complying with reliability requirements influenced by, for example, base current distribution, requires design optimization.

Thus, there is a need for an improved bipolar junction transistor.

### SUMMARY

An example of the present disclosure relates to a semiconductor device comprising a semiconductor body having a first surface and a second surface opposite to the first surface along a vertical direction. The semiconductor device includes a bipolar junction transistor, BJT. The BJT includes an emitter region electrically connected to an emitter contact at the first surface, a base region electrically connected to a base contact at the first surface, and a collector region electrically connected to a collector contact. The BJT further includes a dielectric isolation structure extending into the semiconductor body from the first surface. The dielectric isolation structure includes a first sub-structure arranged, along a first lateral direction, between the emitter contact and the base contact. The BJT further includes a field plate structure including a field plate dielectric and a field plate electrode on the field plate dielectric. A first part of the field plate structure is arranged on the first surface of the semiconductor body and a second part of the field plate structure is arranged on the first sub-structure of the dielectric isolation structure.

Another example of the present disclosure relates to a method of manufacturing a semiconductor device. The method includes providing a semiconductor body having a first surface and a second surface opposite to the first surface along a vertical direction. The method further includes forming a bipolar junction transistor, BJT, in the semiconductor body. Forming the BJT includes forming an emitter region electrically connected to an emitter contact at the first surface. Forming the BJT further includes forming a base region electrically connected to a base contact at the first surface. Forming the BJT further includes forming a collector region electrically connected to a collector contact. Forming the BJT further includes forming a dielectric isolation structure extending into the semiconductor body from the first surface. The dielectric isolation structure includes a first sub-structure arranged, along a first lateral direction, between the emitter contact and the base contact. Forming the BJT further includes forming a field plate structure including a field plate dielectric and a field plate electrode on the field plate dielectric. A first part of the field plate structure is arranged on the first surface of the semiconductor body and a second part of the field plate structure is arranged on the first sub-structure of the dielectric isolation structure.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of semiconductor devices and together with the description serve to explain principles of the examples. Further examples are described in the following detailed description and the claims.

FIGS. 1 to 3 are partial cross-sectional views for illustrating configuration examples of pnp bipolar junction transistors.

FIG. 4 is a schematic top view for illustrating an exemplary design of a pnp bipolar junction transistor.

FIG. 5 schematically and exemplarily shows a configuration example of an integrated circuit.

### DETAILED DESCRIPTION

In the following detailed description, reference is made to the accompanying drawings, which form a part hereof and in which are shown by way of illustrations specific examples of BJTs. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” describes a permanent low-resistive connection between electrically connected elements, for example a direct contact between the concerned elements or a low-resistive connection via a metal and/or heavily doped semiconductor material. The term “electrically coupled” includes that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact is a non-rectifying electrical junction.

Ranges given for physical dimensions include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of a semiconductor device includes a semiconductor body having a first surface and a second surface opposite to the first surface along a vertical direction. The semiconductor device includes a bipolar junction transistor, BJT. The BJT includes an emitter region electrically connected to an emitter contact at the first surface. The BJT further includes a base region electrically connected to a base contact at the first surface. The BJT further includes a collector region electrically connected to a collector contact. The BJT may further include a dielectric isolation structure extending into the semiconductor body from the first surface. The dielectric isolation structure may include a first sub-structure arranged, along a first lateral direction, between the emitter contact and the base contact. The BJT may further include a field plate structure including a field plate dielectric and a field plate electrode on the field plate dielectric. A first part of the field plate structure may be arranged on the first surface of the semiconductor body and a second part of the field plate structure may be arranged on the first sub-structure of the dielectric isolation structure.

For example, the BJT may be implemented monolithically using a CMOS or mixed technology. Mixed technologies can be used, for example, to form analog circuit blocks in a chip by the bipolar devices included in this technology for providing interfaces to digital systems, and to form digital circuit blocks by the complementary metal-oxide-semiconductor (CMOS) devices included in this technology for providing signal processing, and to form low-, medium- or high-voltage or power blocks by field effect transistors included in this technology. Such mixed technologies are known, for example, as bipolar CMOS-DMOS, BCD technologies or smart power technologies, SPT, and are used in a variety of application areas in the field of e.g. lighting, motor control, automotive electronics, power management for mobile devices, audio amplifiers, power supply, hard disks, printers. The BJT may be part of a BCD or Smart Power chip in one of the above application fields, for example.

The semiconductor body may be based on various semiconductor materials, for example silicon (Si), silicon-on-insulator (SOI), silicon-sapphire (SOS), silicon-germanium, germanium, gallium arsenide, silicon carbide, gallium nitride, or other compound semiconductor materials. The semiconductor body may be based on a semiconductor substrate, for example a semiconductor wafer and may include one or more epitaxial layers deposited thereon or may be back-thinned.

The first surface may be a front surface or a top surface of the semiconductor body, and the second surface may be a back surface or a rear surface of the semiconductor body, for example. The semiconductor body may be attached to a lead frame via the second surface, for example. Over the first surface of the semiconductor body, bond pads may be arranged and bond wires may be bonded on the bond pads, for example.

The emitter contact may be part of a wiring area over the semiconductor body. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) or contact line(s) may be formed in openings in the interlayer dielectric structure to electrically connect parts, e.g. metal lines or contact areas, of different wiring levels to one another. For example, the emitter contact may be formed by one or more elements of the wiring area. Likewise, the base contact may be formed by one or more elements of the wiring area. For example, the emitter contact and the base contact may include separate parts of a patterned first wiring level, e.g. a first metal layer.

The dielectric isolation structure may include a single dielectric material or a plurality of merged parts that may differ in material, shape, and/or function, for example. For example, the merged parts of the dielectric isolation structure may be formed by separate processes. For example, the merged parts of the dielectric isolation structure may be parts that are merged along the first lateral direction. For example, the dielectric isolation structure may be an insulating material such as an oxide, e.g., SiO₂, a nitride, e.g., Si₃N₄, a high-k dielectric, or a low-k dielectric, or any combination thereof. For example, the dielectric isolation structure may be formed as a CVD (chemical vapor deposition) oxide. For example, the bottom side of the dielectric isolation structure may be located at a bottom side of a recess or trench in the semiconductor body. In this case, the dielectric isolation structure may be formed as a shallow trench isolation, STI. The bottom side of the dielectric isolation structure may also be a bottom side of an oxidized part of the semiconductor body, e.g. a bottom side of a local oxidation of silicon, LOCOS. On the dielectric isolation structure, e.g. directly adjoining a top side of at least part of the dielectric isolation structure, an interlayer dielectric structure of the wiring area may be arranged. The interlayer dielectric structure may be arranged between the dielectric isolation structure and a first wiring level of the wiring area over the first surface of the semiconductor body. The first wiring level may be a wiring level of the wiring area that is closest to the first surface of the semiconductor body. The first wiring level may include separate parts, e.g. separate metal layer portions. The separate parts may include parts of the emitter contact and/or the base contact. On the dielectric isolation structure, e.g. directly adjoining a top side of at least part of the dielectric isolation structure, the field plate dielectric of the field plate structure may be arranged. The field plate electrode may be formed as part of a patterned highly doped semiconductor layer, e.g. polycrystalline silicon layer, in the wiring area, for example. The patterned semiconductor layer, e.g. highly doped polysilicon layer, may be used as a gate electrode in other circuit parts of the semiconductor body, e.g. in a CMOS circuit block. For example, the field plate structure may laterally extend over a lateral end of the emitter region, or may laterally extend up to the lateral end of the emitter region, or may end before the lateral end of the emitter region.

By combining the field plate structure and the dielectric isolation structure, device degradation, e.g. caused by drift mechanisms associated with charge accumulation in the dielectric isolation structure caused by device current distribution, may be avoided or counteracted. This may allow for improving device reliability, for example.

For example, the base contact may be arranged between the emitter contact and a collector contact along the first lateral direction. The collector region may be electrically connected to the collector contact at the first surface. Similar to the emitter and/or base contact, the collector contact may be formed by one or more elements of the wiring area. For example, the collector, base, and emitter contacts may include separate parts of a patterned first wiring level, e.g. a first metal layer.

For example, a lateral extent of the first part of the field plate structure along the first lateral direction may have a value in a range from 30% to 90%, or in a range from 30% to 70%, or in a range from 40% to 60%, of a lateral extent of the first sub-structure of the dielectric isolation structure along the first lateral direction at the first surface.

For example, the first part of the field plate structure may protrude laterally over the dielectric isolation structure toward the emitter contact. In other words, the first part of the field plate structure may be a part that laterally extends over a side end of the dielectric isolation structure toward the emitter contact.

For example, the first part of the field plate structure may protrude laterally over the dielectric isolation structure toward the base contact. In other words, the first part of the field plate structure may be a part that laterally extends over a side end of the dielectric isolation structure toward the base contact.

For example, a lateral extent of the second part of the field plate structure along the first lateral direction may be smaller than a lateral extent of the first sub-structure of the dielectric isolation structure along the first lateral direction at the first surface. In other words, only a part of the first sub-structure of the dielectric isolation structure may be covered by the field plate structure. The other part not covered by the field plate structure may be covered by part of the interlayer dielectric structure of the wiring area, for example.

For example, the field plate electrode may be electrically coupled to the emitter contact. This may allow for suppressing undesired parasitic device behavior. For example, the field plate electrode may be electrically coupled to the emitter contact via a conductive path in the wiring area inside or outside of an active area of the BJT.

For example, a vertical distance from a bottom side of the first sub-structure of the dielectric isolation structure to the first surface has a value in a range from 10% to 30% of a vertical distance from a bottom side of the base region to the first surface. For example, the vertical distance from the bottom side of the first sub-structure of the dielectric isolation structure to the first surface may have a value in a range from 100 nm to 500 nm.

For example, the dielectric isolation structure may include a second sub-structure arranged, along the first lateral direction, between the base contact and the collector contact. The field plate structure may be omitted, e.g. be absent, on the second sub-structure of the dielectric isolation structure. Since device degradation, e.g. caused by drift mechanisms associated with charge accumulation in the dielectric isolation structure caused by device current distribution, may be more pronounced around the first sub-structure, the second sub-structure may not be protected by a field plate structure. This may allow for a more compact device layout, for example.

For example, a lateral extent of the first sub-structure of the dielectric isolation structure along the first lateral direction at the first surface may be larger than a lateral extent of the second sub-structure of the dielectric isolation structure along the first lateral direction at the first surface.

For example, the BJT may be a pnp BJT and the semiconductor body may be a p-doped semiconductor substrate. For example, the semiconductor substrate may be formed of a base substrate, e.g. wafer or a die of a wafer that has been diced, having none, one or even more semiconductor layers such as epitaxial semiconductor layers on the base substrate. For example, the semiconductor substrate may be a Czochralski (CZ), e.g. a magnetic Czochralski, MCZ, or a float zone (FZ), or an epitaxially deposited silicon semiconductor substrate.

For example, a doping concentration profile in the base region and a doping concentration profile in the collector region are configured for a collector-to-base breakdown voltage in a range from 5 V to 20 V. For example, the breakdown voltage may be adjusted, inter alia, by ion implantation parameters, e.g. dose and energy, of the base region. The base region may be formed as an n-doped semiconductor well in the semiconductor body.

For example, in a top view, the field plate structure may at least partially surround the emitter region. For example, the field plate structure may be arranged along all or part of, e.g. segments spaced from one another, a path that goes around the emitter region. The path may have a shape adapted to a shape of the emitter region. For example, the path may form a circle, an ellipse, a polygon such as a square or a rectangle or a hexagon or an octagon.

An example of an integrated circuit may include the semiconductor device as described in any of the examples herein. The integrated circuit may further include at least one of a voltage reference circuit and a temperature sensor circuit. The at least one of the voltage reference circuit and the temperature sensor circuit may include the BJT.

For example, the integrated circuit may further include a CMOS circuit block. In some examples, the integrated may further include a power semiconductor device block, e.g. a circuit block including a transistor cell area including DMOS (Double-diffused Metal Oxide Semiconductor), or MOS (Metal Oxide Semiconductor), or IGBT (Insulated Gate Bipolar Transistor), or JFET (Junction Field Effect Transistor) cells. In addition or as an alternative, the integrated circuit may further include a memory circuit block, e.g. a non-volatile memory circuit block such as a Flash memory, EEPROM (Electrically Erasable and Programmable Read Only Memory) or OTP (One Time Programmable).

Details with respect to structure, or function, or technical benefit of features described above with respect to a semiconductor device or integrated circuit likewise apply to the exemplary methods described herein. Processing the semiconductor body or substrate may comprise one or more optional additional features corresponding to one or more aspects mentioned in connection with the proposed concept or one or more examples described above or below.

An example of the present disclosure relates to a method of manufacturing a semiconductor device. The method includes providing a semiconductor body having a first surface and a second surface opposite to the first surface along a vertical direction. The method further includes forming a bipolar junction transistor, BJT, in the semiconductor body. Forming the BJT includes forming an emitter region electrically connected to an emitter contact at the first surface. Forming the BJT further includes forming a base region electrically connected to a base contact at the first surface. Forming the BJT further includes forming a collector region electrically connected to a collector contact. Forming the BJT may further include forming a dielectric isolation structure extending into the semiconductor body from the first surface. The dielectric isolation structure may include a first sub-structure arranged, along a first lateral direction, between the emitter contact and the base contact. Forming the BJT may further include forming a field plate structure including a field plate dielectric and a field plate electrode on the field plate dielectric. A first part of the field plate structure may be arranged on the first surface of the semiconductor body and a second part of the field plate structure may be arranged on the first sub-structure of the dielectric isolation structure.

For example, a lateral extent of the first part of the field plate structure along the first lateral direction may be set to a value in a range from 30% to 90%, or in a range from 30% to 70%, or in a range from 40% to 60% of a lateral extent of the first sub-structure of the dielectric isolation structure along the first lateral direction at the first surface.

For example, forming the dielectric isolation structure may further include forming a second sub-structure arranged, along the first lateral direction, between the base contact and the collector contact. The field plate structure may be omitted, e.g. be absent, on the second sub-structure of the dielectric isolation structure.

For example, a lateral extent of the first sub-structure of the dielectric isolation structure along the first lateral direction at the first surface may be set to a larger value than a lateral extent of the second sub-structure of the dielectric isolation structure along the first lateral direction at the first surface.

The examples and features described above and below may be combined.

Functional and structural details described with respect to the examples above shall likewise apply to the exemplary examples illustrated in the figures and described further below.

In the following, further examples of semiconductor devices and integrated circuits are explained in connection with the accompanying drawings. Functional and structural details described with respect to the examples above shall likewise apply to the configuration examples illustrated in the figures and described further below. In the illustrated examples, the BJT is a pnp BJT. However, examples described herein may likewise be applied to a npn BJT.

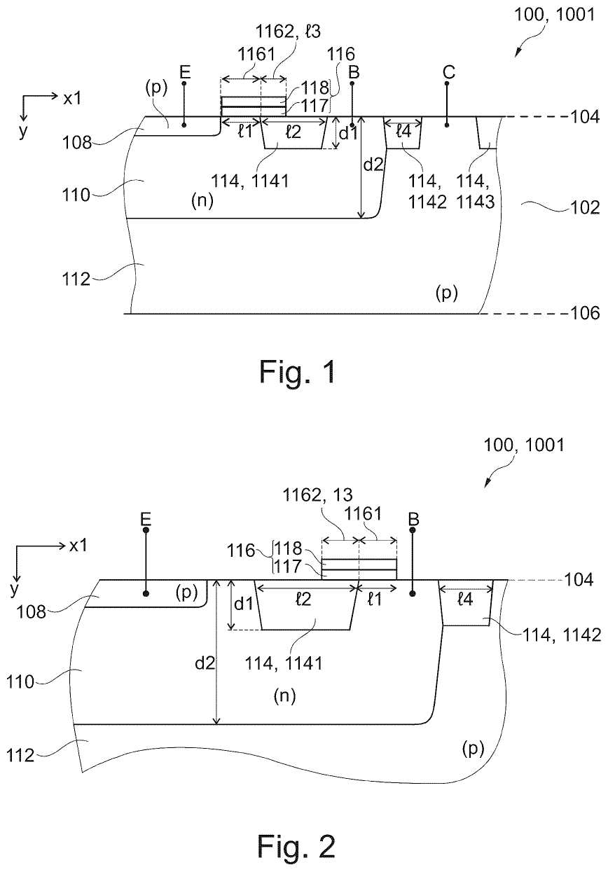

FIG. 1, FIG. 2, and FIG. 3 schematically and exemplarily show configuration examples of a semiconductor device 100 including a BJT 1001. A semiconductor body 102 of the semiconductor device 100 has a first surface 104, e.g. a front surface, and a second surface 106, e.g. a back or rear surface, opposite to the first surface 104. The first and second surface oppose one another along a vertical direction y. A p+-doped emitter region 108 of the BJT 1001 is electrically connected to an emitter contact E at the first surface 104. The emitter contact E may be part of a wiring area over the first surface 104. An n-doped base region 110 of the BJT 1001 is electrically connected to a base contact B at the first surface 104. The n-doped base region 110 may include a highly n-doped contact region at the first surface 104 for improving ohmic contact behavior to the base contact B, for example. Similar to the emitter contact E, the base contact B may be part of the wiring area over the first surface 104. A p-doped collector region 112 of the BJT 1001 is electrically connected to a collector contact C that may also be part of the wiring area over the first surface 104. The p-doped collector region 112 may include a highly p-doped contact region at the first surface 104 for improving ohmic contact behavior to the collector contact C.

A vertical distance d1 from a bottom side of the first sub-structure 1141 of the dielectric isolation structure 114 to the first surface 104 may have a value in a range from 10% to 30% of a vertical distance d2 from a bottom side of the base region 110 to the first surface 104, for example.

The BJT 1001 further includes a dielectric isolation structure 114, e.g. STI or LOCOS, extending into the semiconductor body 102 from the first surface 104. The dielectric isolation structure 114 includes a first sub-structure 1141 arranged, along a first lateral direction x1, between the emitter contact E and the base contact B. The first sub-structure 1141 of the dielectric isolation structure 114 is spaced from the emitter region 108 along the first lateral direction x1. For example, the first sub-structure 1141 of the dielectric isolation structure 114 is spaced from the emitter region 108 along the first lateral direction x1 at the first surface 104. A part of the base region 110 and a part of the semiconductor body 102, respectively, are arranged in the space between the dielectric isolation structure 114 and the emitter region 108. The BJT 1001 further includes a field plate structure 116. The field plate structure 116 includes a field plate dielectric 117 and a field plate electrode 118 on the field plate dielectric 117. A first part 1161 of the field plate structure 116 is arranged on the first surface 104 of the semiconductor body 102 and a second part 1162 of the field plate structure 116 is arranged on the first sub-structure 1141 of the dielectric isolation structure 114. The first part 1161 of the field plate structure 116 is arranged on the first surface 104 of the semiconductor body 102 and the base region 110, respectively, at a position where the first sub-structure 1141 of the dielectric isolation structure 114 is spaced from the emitter region 108 along the first lateral direction x1. That means, there is no first sub-structure 1141 of the dielectric isolation structure 114 below the first part 1161 of the field plate structure 116.

In the configuration example illustrated in FIG. 1, the first part 1161 of the field plate structure 116 protrudes laterally over the dielectric isolation structure 114 toward the emitter contact E. Thus, the first part 1161 of the field plate structure 116 laterally extends over a side end of the dielectric isolation structure 114 toward the emitter contact E.

In the configuration example illustrated in FIG. 2, the first part 1161 of the field plate structure 116 protrudes laterally over the dielectric isolation structure 114 toward the base contact B. Thus, the first part 1161 of the field plate structure 116 laterally extends over a side end of the dielectric isolation structure 114 toward the base contact B.

In the configuration example illustrated in FIG. 3, the second part 1162 of the field plate structure 116 completely covers the dielectric isolation structure 114. The first part 1161 of the field plate structure 116 protrudes laterally over the dielectric isolation structure 114 toward the emitter contact E. A third part 1163 of the field plate structure 116 laterally extends over a side end of the dielectric isolation structure 114 toward the base contact B.

In the configuration examples illustrated in FIGS. 1 to 3, the dielectric isolation structure 114 includes a second sub-structure 1142 arranged, along the first lateral direction x1, between the base contact B and the collector contact C. Other than over the first sub-structure 1141, the field plate structure 116 is omitted on the second sub-structure 1142 of the dielectric isolation structure 114. A lateral extent 12 of the first sub-structure 1141 of the dielectric isolation structure 114 along the first lateral direction x1 at the first surface 104 is larger than a lateral extent l4 of the second sub-structure 1142 of the dielectric isolation structure 114 along the first lateral direction x1 at the first surface 104. The dielectric isolation structure 114 further includes a third sub-structure 1143, wherein the collector contact C is arranged between the second sub-structure 1142 and the third sub-structure 1143.

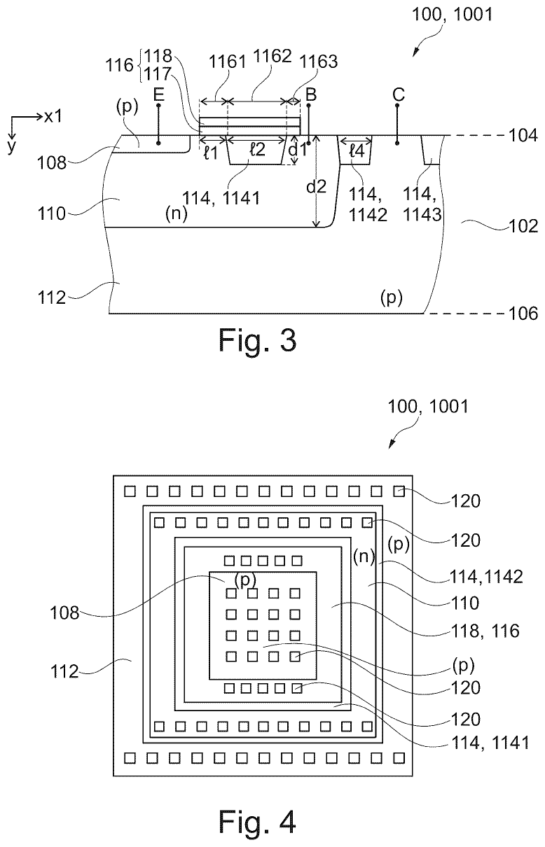

FIG. 4 is a schematic top view for illustrating an exemplary layout of a pnp bipolar junction transistor, e.g. a pnp BJT as illustrated in FIG. 1.

The emitter region 108 is surrounded by the field plate structure 116. The field plate structure 116 is surrounded by the base region 110, and the base region 110 is surrounded by the collector region 112.

Although paths surrounding each of the regions illustrated in FIG. 4 define a square device geometry, the illustrated configuration example is only for illustration purpose, and other device geometries, e.g. circular, ellipsoid, polygonal such as rectangular or hexagonal or octagonal geometries may be used.

Contact plugs 120 are arranged on the emitter region 108 as part of the emitter contact E. The contact plugs 120 are also arranged on the base region 110 as part of the base contact B. The contact plugs are also arranged on the collector region 112 as part of collector contact C. Further contact plugs 120 are arranged on the field plate electrode 118 for electrically coupling the field plate electrode 118 to a reference potential, e.g. to the emitter electrode E.

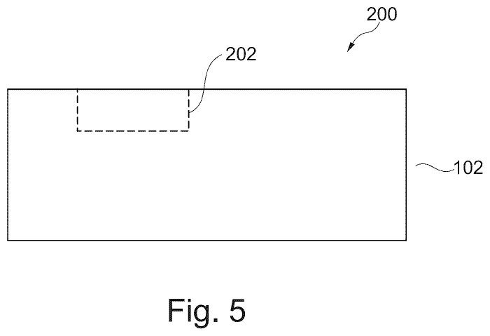

FIG. 5 schematically and exemplarily shows a configuration example of an integrated circuit 200. The integrated circuit 200 includes the semiconductor device 100 as described in any of the examples herein. The semiconductor device 100 is part of a voltage reference or temperature sensor circuit 202. Apart from the voltage reference or temperature sensor circuit 202, other circuit blocks may be part of the integrated circuit 200.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising
a semiconductor body having a first surface and a second surface opposite to the first surface along a vertical direction; and
a bipolar junction transistor (BJT) comprising:
an emitter region electrically connected to an emitter contact at the first surface;
a base region electrically connected to a base contact at the first surface;
a collector region electrically connected to a collector contact;
a dielectric isolation structure extending into the semiconductor body from the first surface, wherein the dielectric isolation structure includes a first sub-structure arranged, along a first lateral direction, between the emitter contact and the base contact; and
a field plate structure including a field plate dielectric and a field plate electrode on the field plate dielectric, wherein a first part of the field plate structure is arranged on the first surface of the semiconductor body and a second part of the field plate structure is arranged on the first sub-structure of the dielectric isolation structure.

2. The semiconductor device of claim 1, wherein the first sub-structure of the dielectric isolation structure is spaced from the emitter region along the first lateral direction.

3. The semiconductor device of claim 1, wherein the dielectric isolation structure is a shallow trench isolation (STI) structure or a local oxidation of silicon (LOCOS) structure.

4. The semiconductor device of claim 1, wherein the base contact is arranged between the emitter contact and the collector contact along the first lateral direction, and wherein the collector region is electrically connected to the collector contact at the first surface.

5. The semiconductor device of claim 1, wherein a lateral extent of the first part of the field plate structure along the first lateral direction has a value in a range from 30% to 90% of a lateral extent of the first sub-structure of the dielectric isolation structure along the first lateral direction at the first surface.

6. The semiconductor device of claim 1, wherein the first part of the field plate structure protrudes laterally over the first sub-structure of the dielectric isolation structure toward the emitter contact.

7. The semiconductor device of claim 1, wherein the first part of the field plate structure protrudes laterally over the first sub-structure of the dielectric isolation structure toward the base contact.

8. The semiconductor device of claim 1, wherein a lateral extent of the second part of the field plate structure along the first lateral direction is smaller than a lateral extent of the first sub-structure of the dielectric isolation structure along the first lateral direction at the first surface.

9. The semiconductor device of claim 1, wherein the field plate electrode is electrically coupled to the emitter contact.

10. The semiconductor device of claim 1, wherein a vertical distance from a bottom side of the first sub-structure of the dielectric isolation structure to the first surface has a value in a range from 10% to 30% of a vertical distance from a bottom side of the base region to the first surface.

11. The semiconductor device of claim 1, wherein the dielectric isolation structure includes a second sub-structure arranged, along the first lateral direction, between the base contact and the collector contact, and wherein the field plate structure is omitted on the second sub-structure of the dielectric isolation structure.

12. The semiconductor device of claim 11, wherein a lateral extent of the first sub-structure of the dielectric isolation structure along the first lateral direction at the first surface is larger than a lateral extent of the second sub-structure of the dielectric isolation structure along the first lateral direction at the first surface.

13. The semiconductor device of claim 1, wherein the BJT is a pnp BJT and the semiconductor body is a p-doped semiconductor substrate.

14. The semiconductor device of claim 1, wherein a doping concentration profile in the base region and a doping concentration profile in the collector region are configured for a collector-to-base breakdown voltage in a range from 5 V to 20 V.

15. The semiconductor device of claim 1, wherein in a top view, the field plate structure at least partially surrounds the emitter region.

16. An integrated circuit, comprising:
the semiconductor device of claim 1;
at least one of a voltage reference circuit and a temperature sensor circuit,
wherein the at least one of the voltage reference circuit and the temperature sensor circuit include the BJT.

17. The integrated circuit of claim 16, further comprising a CMOS circuit block.

18. A method of manufacturing a semiconductor device, the method comprising:
providing a semiconductor body having a first surface and a second surface opposite to the first surface along a vertical direction; and
forming a bipolar junction transistor (BJT) in the semiconductor body,
wherein forming the BJT comprises:
forming an emitter region electrically connected to an emitter contact at the first surface;
forming a base region electrically connected to a base contact at the first surface;
forming a collector region electrically connected to a collector contact;
forming a dielectric isolation structure extending into the semiconductor body from the first surface, wherein the dielectric isolation structure includes a first sub-structure arranged, along a first lateral direction, between the emitter contact and the base contact; and
forming a field plate structure including a field plate dielectric and a field plate electrode on the field plate dielectric, wherein a first part of the field plate structure is arranged on the first surface of the semiconductor body and a second part of the field plate structure is arranged on the first sub-structure of the dielectric isolation structure.

19. The method of claim 18, wherein the first sub-structure of the dielectric isolation structure is spaced from the emitter region along the first lateral direction.

20. The method of claim 18, wherein a lateral extent of the first part of the field plate structure along the first lateral direction is set to a value in a range from 30% to 90% of a lateral extent of the first sub-structure of the dielectric isolation structure along the first lateral direction at the first surface.

21. The method of claim 18, wherein forming the dielectric isolation structure further comprises forming a second sub-structure arranged, along the first lateral direction, between the base contact and the collector contact, and wherein the field plate structure is omitted on the second sub-structure of the dielectric isolation structure.

22. The method of claim 21, wherein a lateral extent of the first sub-structure of the dielectric isolation structure along the first lateral direction at the first surface is set to a larger value than a lateral extent of the second sub-structure of the dielectric isolation structure along the first lateral direction at the first surface.
